(19) United States
(12) Patent Application Publication
(10) Pub. No.: US 2026/0090317 A1
(43) Pub. Date: Mar. 26, 2026

(54) SYSTEM AND METHOD FOR MOUNTING A HOUSING TO A BASE PLATE OF A SEMICONDUCTOR MODULE

(71) Applicant: Infineon Technologies AG, Neubiberg (DE)

(72) Inventors: Georg Troska, Fröndenberg (DE); Christian Steininger, Soest (DE); Guido Strotmann, Anröchte (DE); Florian Dreps, Paderborn (DE)

(21) Appl. No.: 19/328,691

(22) Filed: Sep. 15, 2025

(30) Foreign Application Priority Data
Sep. 25, 2024 (DE) 102024127787.4

(51) Int. Cl. H01L 21/67; H01L 21/48

(52) U.S. Cl. CPC H10P 72/0438; H10P 72/0606; H10W 70/023

(57) ABSTRACT

A system includes a pattern recognition unit, a pick and place unit and a control unit. The pattern recognition unit determines an actual position of a connection area arranged on or above a substrate of a semiconductor module, the substrate being arranged on a base plate. The pattern recognition unit also determines an actual position of a first end of a terminal element attached to a housing arranged on the base plate, such that the substrate is arranged within a volume defined by the housing. The control unit determines a deviation between the actual position of the first end of the terminal element with respect to the actual position of the connection area. The pick and place unit moves to the actual position of the first end, picks up the first end of the terminal element, and subsequently moves the first end to the actual position of the connection area.

### TECHNICAL FIELD

The instant disclosure relates to a system and method for mounting a housing to a base plate of a semiconductor module, in particular a housing with terminal elements attached thereto.

### BACKGROUND

Power semiconductor module arrangements often include one or more substrates arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and (optionally) a second metallization layer deposited on a second side of the substrate layer. The controllable semiconductor elements are mounted, for example, on the first metallization layer. The one or more substrates may be arranged on a base plate. An electrical connection between the inside and the outside of the housing may be implemented by means of terminal elements. One or more terminal elements may be (permanently) attached to the housing in suitable ways. A first end of each terminal element is arranged on and electrically coupled to a substrate of the one or more substrates. Due to tolerances occurring during the assembly of the semiconductor module, however, it may not be guaranteed that the first ends of the one or more terminal elements are always arranged in their desired positions with respect to the respective substrate, when the semiconductor module is fully assembled. For this reason, larger areas on the respective substrates may be kept free of other components such that a reliable connection may be formed between the one or more terminal elements and the respective substrates even if tolerances occur. This, however, increases the size and therefore the cost of the semiconductor module.

There is a need for a system and a method which allow to assemble a semiconductor module in a space saving and cost effective manner.

### SUMMARY

A system comprises a pattern recognition unit, a pick and place unit, and a control unit, wherein the pattern recognition unit is configured to determine an actual position of a connection area, wherein the connection area is arranged on or above a substrate of a semiconductor module, and the substrate is arranged on a base plate, the pattern recognition unit is further configured to determine an actual position of a first end of a terminal element, wherein the terminal element is attached to a housing, and the housing is arranged on the base plate such that the substrate is arranged within a volume defined by the housing, the control unit is configured to determine a deviation between the actual position of the first end of the terminal element with respect to the actual position of the connection area, and the pick and place unit is configured to move to the actual position of the first end as determined by the pattern recognition unit, and pick up the first end of the terminal element, and subsequently move the first end to the actual position of the connection area as determined by the pattern recognition unit.

A method comprises determining an actual position of a connection area by means of a pattern recognition unit, wherein the connection area is arranged on or above a substrate of a semiconductor module, and the substrate is arranged on a base plate. The method further comprises determining an actual position of a first end of a terminal element by means of the pattern recognition unit, wherein the terminal element is attached to a housing, and the housing is arranged on the base plate such that the substrate is arranged within a volume defined by the housing. The method further comprises determining a deviation between the actual position of the first end of the terminal element with respect to the actual position of the connection area, moving a pick and place unit to the actual position of the first end as determined by the pattern recognition unit, picking up the first end of the terminal element by means of the pick and place unit, and subsequently moving the first end to the actual position of the connection area as determined by the pattern recognition unit by means of the pick and place unit.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module.

FIG. 2 is a three dimensional view of a housing with a plurality of terminal elements attached thereto.

FIGS. 3A to 3C schematically illustrate respective top views of base plates with substrates arranged thereon.

FIG. 4 schematically illustrates a system according to embodiments of the disclosure.

FIG. 5 schematically illustrates a sidewall of a housing with terminal elements attached thereto.

FIGS. 6A to 6C schematically illustrate different terminal elements.

FIG. 7 schematically illustrates a tool for positioning a first end of a terminal element on a substrate.

FIG. 8 schematically illustrates a method according to embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

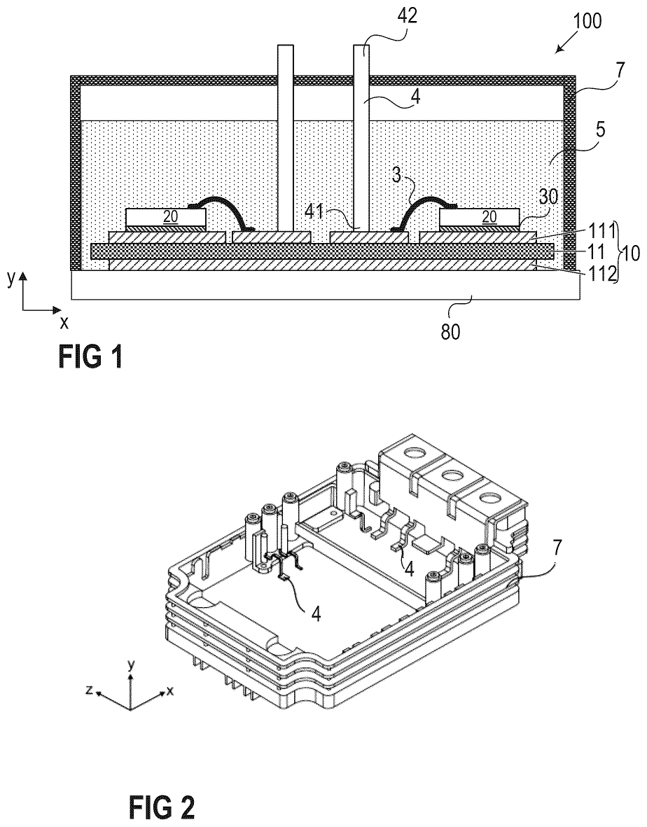

Referring to FIG. 1, a cross-sectional view of a semiconductor module 100 is illustrated. The semiconductor module 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 80 which forms a base surface of the housing 7, while the housing 7 itself solely comprises sidewalls and a cover. The cover of the housing 7 is generally optional and may also be omitted. It is generally possible that more than one substrate 10 is arranged on a single base plate 80 and within the same housing 7.

One or more semiconductor bodies 20 may be arranged on each of the one or more substrates 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the one or more substrates 10. In FIG. 1, only one substrate 10 and two semiconductor bodies 20 arranged thereon are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second end 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Terminal elements 4 may also be attached to the housing 7, as will be described with respect to FIG. 2 below. Any other suitable implementation is generally possible. The terminal elements 4 may consist of or include a metal such as copper, aluminum, gold, silver, or any alloys thereof, for example. The terminal elements 4 may be electrically and mechanically connected to the substrate 10 by an electrically conductive connection layer (not specifically illustrated for the terminal elements 4). Such an electrically conductive connection layer generally may be a solder layer, a layer of an electrically conductive adhesive, or a layer of a sintered metal powder, e.g., a sintered silver powder, for example.

Conventional semiconductor modules 100 generally further include an encapsulant or casting compound 5. The casting compound 5 may consist of or include a cured silicone gel or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

Referring to FIG. 2, a housing 7 is schematically illustrated, the housing 7 comprising sidewalls and a plurality of terminal elements 4 attached to the sidewalls. When the housing 7 is mounted to a base plate 80 to form a semiconductor module (see, e.g., semiconductor module 100 of FIG. 1), the terminal elements 4 are generally already attached to the housing 7. That is, when the housing 7 is arranged on the base plate 80, the first ends 41 of the terminal elements 4 will be arranged at fixed positions with respect to the housing 7, to the base plate 80 and, therefore, with respect to the one or more substrates 10 arranged on the base plate 80. When the housing 7 has been arranged on and attached to the base plate 80, each first end 41 of the first ends 41 of the one or more terminal elements 4 may be permanently connected to a respective one of the one or more substrates 10.

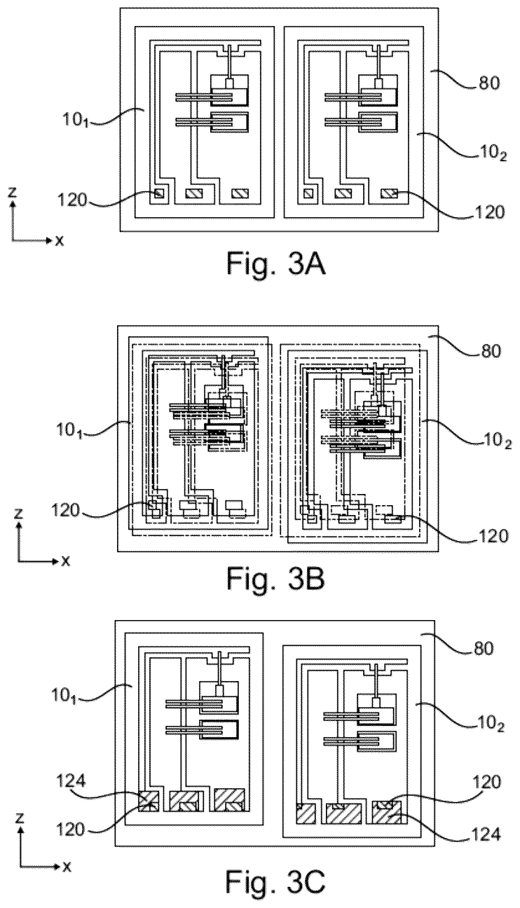

Now referring to FIG. 3A, two substrates 10₁, 10₂ on a base plate 80 are schematically illustrated. FIG. 3A schematically illustrates the two substrates 10₁, 10₂ in a desired position on the base plate 80. However, due to normal production tolerances, it may not always be guaranteed that the substrates 10₁, 10₂ are actually always mounted in their desired positions on the base plate 80. The positions of the substrates 10₁, 10₂ may vary to a certain degree. Generally, a shift (shift or rotation) of up to a few millimeters is possible. In different arrangements illustrated in FIGS. 3A to 3C, the first metallization layers 111 arranged on the respective dielectric insulation layers 11 are visible. Further, semiconductor bodies as well as electrical connections (bonding wires) are schematically illustrated. FIGS. 3A to 3C further schematically illustrate a plurality of connection areas 120 on each of the substrates 10₁, 10₂. The connection areas 120 are areas on the substrates 10₁, 10₂ (i.e. on the first metallization layers 111) to which first ends 41 of terminal elements 4 may be attached. As described above, terminal elements 4 may be attached to a housing 7 of the semiconductor module. The housing 7 is arranged on the base plate 80 after the substrates 10₁, 10₂ have been arranged thereon. As the terminal elements 4 are attached to the housing 7, the position of the first ends 41 with respect to the housing 7 is generally fixed. The housing 7 is generally arranged on the base plate 80 such that the sidewalls of the housing 7 extend along the edges of the base plate 80. That is, the positions of the first ends 41 of the one or more terminal elements 4 are also essentially fixed with respect to the base plate 80. Certain tolerances, however, may also occur when mounting the housing 7 to a base plate 80.

Due to the tolerances that may occur when mounting the substrates 10₁, 10₂ to the base plate 80, and when mounting the housing 7 to the base plate 80, there is a risk that the first ends 41 are not aligned with their respective connection areas 120 when the housing 7 is in its final mounting position on the base plate 80. FIG. 3B schematically illustrates the desired positions of the substrates 10₁, 10₂ (dashed lines), as well as their actual positions (solid lines), which in this example differ from the desired positions due to production tolerances during the step of attaching the substrates 10₁, 10₂ to the base plate 80. If a substrate 10₁, 10₂ is not arranged in its desired position on the base plate 80, this may result in the first ends 41 of the terminal elements 4 attached to the housing 7 being arranged at a certain distance from the respective connection areas 120, if the position of the first ends 41 is chosen to be aligned with the desired position of the respective connection areas 120.

For this reason, enlarged connection areas 124 may be provided on the substrates 10₁, 10₂, as is schematically illustrated in FIG. 3C. That is, more space may be reserved on the individual substrates 10₁, 10₂ for connecting the first ends 41 of the one or more terminal elements 4 thereto than is actually needed to form the connection. No other elements of the semiconductor module may be arranged on the enlarged connection areas 124. However, irrespective of any tolerances during the steps of mounting the substrates 10₁, 10₂ to the base plate 80, and mounting the housing 7 with the terminal elements 4 attached thereto to the base plate 80, the first ends 41 of the one or more terminal elements 4 will always be arranged on a respective one of the enlarged connection areas 124. Providing enlarged connection areas 124 on a substrate 10, however, increases the size of the semiconductor module and, therefore, also its costs.

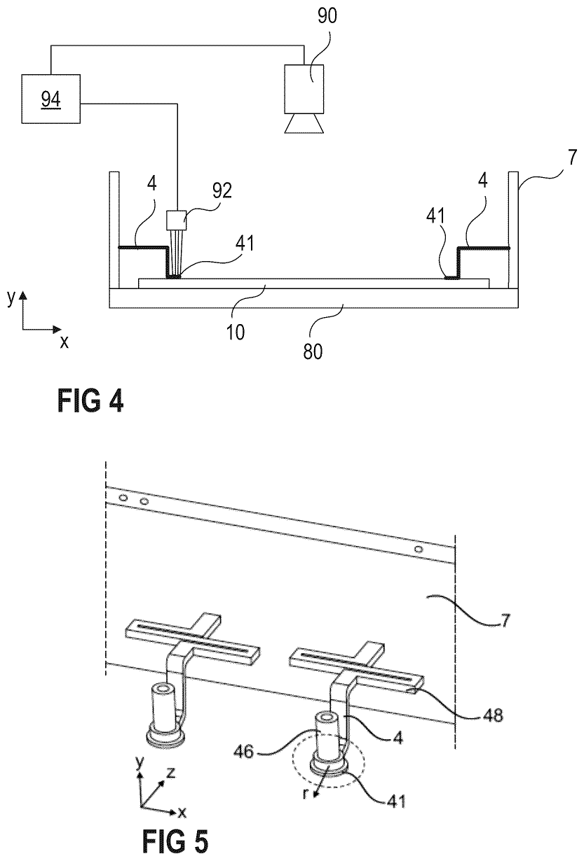

Referring to FIG. 4, a system according to embodiments of the disclosure is schematically illustrated. The described system allows to correctly position the first ends 41 of one or more terminal elements 4 on the respective connection areas 120 on the one or more substrates 10₁, 10₂. The size of the connection areas 120 does not need to be enlarged. Each connection area 120 only needs to be large enough to be able to form a stable connection between the first ends 41 of the terminal elements 4 and the respective connection areas 120. No tolerances need to be considered. In this way, the semiconductor module may be manufactured being small in size and at low costs.

A system according to embodiments of the disclosure comprises a pattern recognition unit 90, a pick and place unit 92, and a control unit 94. The pattern recognition unit 90 is configured to determine an actual position of a connection area 120. As described above, the connection area 120 is arranged or provided on a substrate 10 of a semiconductor module, and the substrate 10 is arranged on a base plate 80. It is also contemplated that a connection area 120 might be arranged above the substrate, e.g., on top of a semiconductor die 20, instead of or in addition to a connection area 120 on the substrate 10. The pattern recognition unit 90 is further configured to determine an actual position of a first end 41 of a terminal element 4. The terminal element 4 is attached to a housing 7, and the housing 7 is arranged on the base plate 80 such that the substrate 10 is arranged within a volume defined by the housing 7. The control unit 94 is configured to determine a deviation between the actual position of the first end 41 of the terminal element 4 with respect to the actual position of the connection area 120, and the pick and place unit 92 is configured to move to the actual position of the first end 41 as determined by the pattern recognition unit 90, and pick up the first end 41 of the terminal element 4, and subsequently move the first end 41 to the actual position of the connection area 120 as determined by the pattern recognition unit 90. In particular, the pick and place unit 92 moves the first end 41 to the actual position of the connection area 120, if the actual position of the first end 41 differs from the actual position of the connection area 120. If the actual position of the first end 41 corresponds to the actual position of the connection area 120, it is generally not necessary to move the first end 41 before forming the connection. When the first end 41 is aligned with the respective connection area 120, a permanent electrical and mechanical connection may be formed between the first end 41 and the connection area 120.

Moving the first end 41 to the actual position of the connection area 120 may not be possible with conventional terminal elements 4. Conventional terminal elements 4 are generally comparably stiff and do not allow any significant movement of the first end 41. However, as mentioned above, an actual position of the first end 41 of a terminal element 4 may differ from the actual position of the connection area 120 by up to a few millimeters. Therefore, the housing 7 may be equipped with terminal elements 4 that are flexible to a certain degree. FIG. 5 schematically illustrates a sidewall of a housing 7 with two terminal elements 4 attached thereto. Each of the terminal elements 4 in this example comprises a flexible portion 48. The flexible portion 48 allows a movement of the first end within a defined radius r. This radius r may be up to several millimeters, e.g., between 0 and 5 mm. In the example illustrated in FIG. 5, the flexible portion 48 is implemented by means of a meandering shape of the terminal element 4 in a section between the sidewall of the housing 7 and the first end 41. This, however, is only an example. The flexible portion 48 may generally be implemented in any suitable way. For example, the flexible portion 48 may comprise a stack comprising a plurality of flat woven ropes stacked above one another. According to even further examples, the flexible portion 48 may comprise one or more braided wires, wherein each of the one or more braided wires comprises a plurality of separate wires that are braided to form the braided wire. It is even possible that the flexible portion 48 comprises a plurality of electrically conducting foils stacked above one another. Any other suitable implementation is also possible.

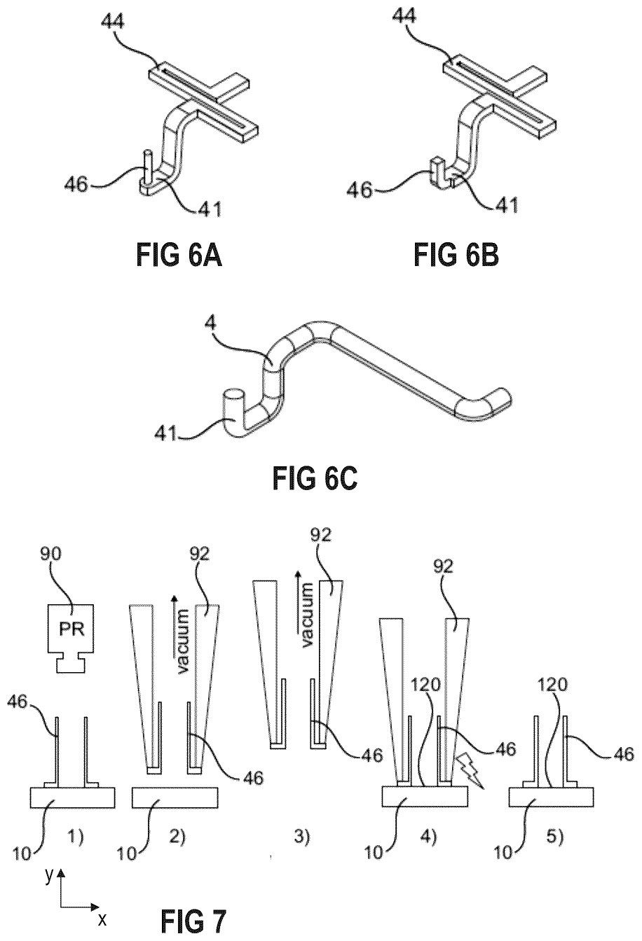

The first end 41 may be formed by a portion of the terminal element 4 which extends in parallel to the base plate 80 and the one or more substrates 10₁, 10₂ arranged thereon, when the one or more substrates 10₁, 10₂ and the housing 7 are mounted to the base plate 80, as is exemplarily illustrated in FIG. 4. It is generally possible to pick up such a flat first end 41 by means of a suitable pick and place unit 92. However, according to further embodiments, the first end 41 of a terminal element 4 may comprise a first portion extending in parallel to the base plate 80 and the one or more substrates 10₁, 10₂ arranged thereon, and a second portion extending in a direction perpendicular to the base plate 80 and the one or more substrates 10₁, 10₂ arranged thereon. Alternatively (instead of the second portion), a protrusion 46 may be connected to the first end 41, wherein the first end 41 extends in parallel to the base plate 80 and the one or more substrates 10₁, 10₂ arranged thereon, and the protrusion 46 extends in a direction perpendicular to the base plate 80 and the one or more substrates 10₁, 10₂ arranged thereon. A protrusion 46 connected to the first end 41 is exemplarily illustrated in FIG. 5. In the example illustrated in FIG. 5, the protrusion 46 has the shape of a sleeve. In an alternative example illustrated in FIG. 6A, the protrusion 46 has the shape of a simple pin, the pin having a round cross-section. In an alternative example illustrated in FIG. 6B, the protrusion 46 has the shape of a pin, the pin having a square cross-section.

In the examples illustrated in FIGS. 6A and 6B, the flexible portion 44 is implemented by means of a meandering shape of the terminal element 4 in a section between the sidewall of the housing 7 and the first end 41, similar to what has been described with respect to FIG. 5. Referring to FIG. 6C, it is alternatively also possible to implement at least a part of the terminal element 4 (e.g., a part of the terminal element 4 extending between the sidewall of the housing 7 and the respective substrate 10) by means of a simple wire. The wire may have a certain thickness in order to prevent it from breaking, but may be flexible enough to allow for a movement of at least the first end 41 within a defined radius. In this example, a first section of a first end 41 of the wire may extend in parallel to the base plate 80 and the respective substrate 10, when the housing 7 is arranged on the base plate 80 (housing 7 not specifically illustrated in FIGS. 6A, 6B and 6C), and a second section of the first end 41 may extend in a direction perpendicular to the base plate 80 and the respective substrate 10, when the housing 7 is arranged on the base plate 80.

The protrusion 46 or the second section of the first end 41 extending in a direction perpendicular to the base plate 80 and the respective substrate 10, when the housing 7 is arranged on the base plate 80, facilitate the handling and repositioning of the first end 41 by means of the pick and place unit 92. Referring to FIG. 7, the pick and place unit 92 may be further configured to form a permanent connection between the first end 41 of the terminal element and the connection area 120. In this example, the pick and place unit 92 may comprise a sonotrode, a transducer, and a suction device (transducer and suction device not explicitly illustrated in FIG. 7). The transducer may be coupled to the sonotrode and configured to vibrate the sonotrode. The sonotrode may comprise a channel extending through the inside of the sonotrode, and having at least two openings towards the outside of the sonotrode. The suction device may be coupled to a first one of the at least two openings and may be configured to cause the first end 41 of the terminal element 4, or a protrusion 46 connected to the first end 41 to be sucked towards a second one of the at least two openings. This is schematically illustrated for a protrusion 46 in FIG. 7. In this example, the pick and place unit 92 picks up the first end 41 by inserting the protrusion 46 into the channel formed in the sonotrode. The suction device sucks the protrusion 46 into the channel such that the pick and place unit 92 may pick up the first end 41 and move it to its desired position on the connection area 120. The pick and place unit 92 may then place the first end 41 on the connection area and perform an ultrasonic welding process, thereby connecting the first end 41 to the connection area. That is, the pick and place unit 92 itself may perform the connection process.

Picking up the first end 41 by means of a suction device, however, is only an example. The pick and place unit 92 may generally pick up the first end 41 or the protrusion 46 in any other suitable way. For example (example not specifically illustrated), the pick and place unit 92 may comprise a sonotrode, a transducer, and a gripping tool. The transducer may be coupled to the sonotrode and may be configured to vibrate the sonotrode. The gripping tool may be configured to grip the first end 41 of the terminal element 4, or a protrusion 46 connected to the first end 41.

According to another example, the pick and place unit 92 may only be configured to move the first end 41 to its desired position on the connection area 120. An additional tool may then be used to form the connection. That is, the system may further comprise a connecting unit, wherein the connecting unit is separate and distinct from the pick and place unit 92, and is configured to form a permanent connection between the first end 41 of the terminal element and the connection area 120. In this example, the connecting unit may comprise a transducer and a sonotrode, wherein the transducer is coupled to the sonotrode and configured to vibrate the sonotrode. The pick and place unit 92 may comprise a channel and a suction device, wherein the channel extends through the pick and place unit 92, and has at least two openings towards the outside of the pick and place unit 92. The suction device is coupled to a first one of the at least two openings and is configured to cause the first end 41 of the terminal element 4, or a protrusion 46 connected to the first end 41 to be sucked towards a second one of the at least two openings. Alternatively, the pick and place unit 92 may comprise a gripping tool configured to grip the first end 41 of the terminal element 4, or a protrusion 46 connected to the first end 41.

In order to be able to pick up the first end 41, the pick and place unit 92 has to move to the actual position of the first end 41. The actual position of the first end 41 may be determined by means of suitable pattern recognition techniques. Pattern recognition techniques are generally known with respect to semiconductor modules. For example, pattern recognition techniques are known by means of which bonding wires may be accurately placed on a substrate or on a semiconductor component, for example. Such pattern recognition techniques may be similarly used to determine the exact position of the first end 41 of a terminal element 4. For example, one or more images may be captured of the base plate 80 and the one or more substrates 10 arranged thereon. According to embodiments of the disclosure, therefore, the pattern recognition unit 90 may comprise at least one camera, wherein the pattern recognition unit 90 is configured to capture at least one image of the base plate 80 and the substrate 10 arranged thereon by means of the at least one camera.

Pattern recognition systems are able to identify and accurately determine characteristic patterns of the surface of the base plate 80 and the one or more substrates 10 arranged thereon. For example, two or more points may be automatically identified in the captured image(s) by means of a respective system in order to create a so-called reference system. In order to compensate for the shift and/or rotation of a substrate 10 on the base plate 80, or, more precisely, a shift and/or rotation of a substrate 10 with respect to a standard coordinate system as defined by the respective pattern recognition unit 90, the at least two points may be used to generate a mathematical function with which any shifts and/or rotations may be compensated. That is, a shift of the at least two points from a standard coordinate system may be determined and, subsequently the actual positions of the one or more substrates 10 and/or of any elements arranged on the one or more substrates 10 may be determined based on the determined shift of the two points. Pattern recognition, however, may alternatively be implemented in any other suitable way.

The same or different pattern recognition techniques may also be used to determine the actual position of the connection area 120. Once the actual position of the first end 41 and the actual position of the respective connection area 120 are known, it may be determined whether the positions correspond to each other. If the actual position of the first end 41 and the actual position of the connection area 120 do not correspond to each other, the first end 41 may be moved to the actual position of the connection area 120 by means of the pick and place unit 92. In particular, the pick and place unit 92 moves to the actual position of the first end 41 as determined by the pattern recognition unit 90, picks up the first end 41 of the terminal element 4, and subsequently moves the first end 41 to the actual position of the connection area 120 as determined by the pattern recognition unit 90. A permanent connection may then be formed between the first end 41 and the connection area 120.

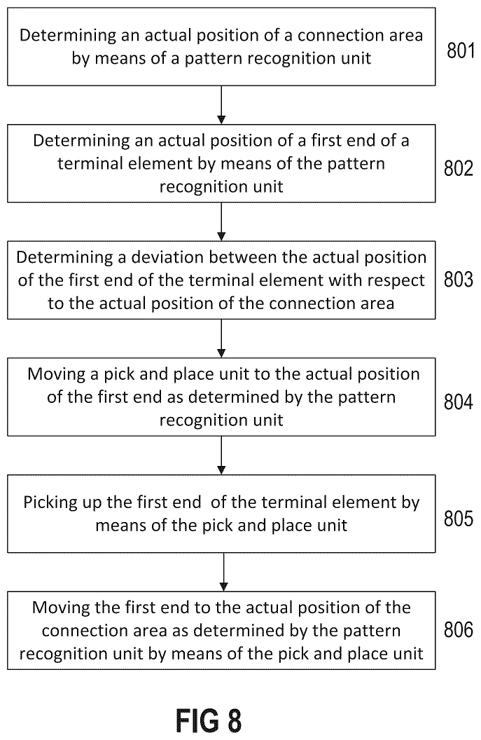

Now referring to FIG. 8, a method according to embodiments of the disclosure is schematically illustrated. The method comprises determining an actual position of a connection area 120 by means of a pattern recognition unit 90 (step 801), wherein the connection area 120 is arranged on a substrate 10 of a semiconductor module, and the substrate 10 is arranged on a base plate 80. The method further comprises determining an actual position of a first end 41 of a terminal element 4 by means of the pattern recognition unit 90 (step 802), wherein the terminal element 4 is attached to a housing 7, and the housing 7 is arranged on the base plate 80 such that the substrate 10 is arranged within a volume defined by the housing 7. The method further comprises determining a deviation between the actual position of the first end 41 of the terminal element 4 with respect to the actual position of the connection area 120 (step 803), moving a pick and place unit 92 to the actual position of the first end 41 as determined by the pattern recognition unit 90 (step 804), picking up the first end 41 of the terminal element 4 by means of the pick and place unit 92 (step 805), and subsequently moving the first end 41 to the actual position of the connection area 120 as determined by the pattern recognition unit 90 by means of the pick and place unit 92 (step 806).

The method may further comprise forming a permanent connection between the first end 41 of the terminal element 4 and the connection area 120. According to some examples, forming a permanent connection between the first end 41 of the terminal element 4 and the connection area 120 may comprise performing an ultrasonic welding process.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system, comprising:
a pattern recognition unit;
a pick and place unit; and
a control unit,
wherein the pattern recognition unit is configured to determine an actual position of a connection area arranged on or above a substrate of a semiconductor module, the substrate being arranged on a base plate,
wherein the pattern recognition unit is further configured to determine an actual position of a first end of a terminal element attached to a housing, the housing being arranged on the base plate such that the substrate is arranged within a volume defined by the housing,
wherein the control unit is configured to determine a deviation between the actual position of the first end of the terminal element with respect to the actual position of the connection area,
wherein the pick and place unit is configured to move to the actual position of the first end determined by the pattern recognition unit, and pick up the first end of the terminal element and subsequently move the first end to the actual position of the connection area determined by the pattern recognition unit.

2. The system of claim 1, wherein the pick and place unit is further configured to form a permanent connection between the first end of the terminal element and the connection area.

3. The system of claim 2,
wherein the pick and place unit comprises a sonotrode, a transducer, and a suction device,
wherein the transducer is coupled to the sonotrode and configured to vibrate the sonotrode to form a permanent connection between the first end of the terminal element and the connection area,
wherein the sonotrode comprises a channel extending through the inside of the sonotrode and having at least two openings towards the outside of the sonotrode, and
wherein the suction device is coupled to a first one of the at least two openings and is configured to cause the first end of the terminal element, or a protrusion connected to the first end, to be sucked towards a second one of the at least two openings.

4. The system of claim 2,
wherein the pick and place unit comprises a sonotrode, a transducer, and a gripping tool,
wherein the transducer is coupled to the sonotrode and configured to vibrate the sonotrode to form a permanent connection between the first end of the terminal element and the connection area, and
wherein the gripping tool is configured to grip the first end of the terminal element or a protrusion connected to the first end.

5. The system of claim 1, further comprising:
a connecting unit configured to form a permanent connection between the first end of the terminal element and the connection area.

6. The system of claim 5,
wherein the connecting unit comprises a transducer and a sonotrode,
wherein the transducer is coupled to the sonotrode and configured to vibrate the sonotrode to form a permanent connection between the first end of the terminal element and the connection area,
wherein the pick and place unit comprises a channel and a suction device,
wherein the channel extends through the pick and place unit and has at least two openings towards the outside of the pick and place unit, and
wherein the suction device is coupled to a first one of the at least two openings and is configured to cause the first end of the terminal element or a protrusion connected to the first end to be sucked towards a second one of the at least two openings.

7. The system of claim 5,
wherein the connecting unit comprises a transducer and a sonotrode,
wherein the transducer is coupled to the sonotrode and configured to vibrate the sonotrode to form a permanent connection between the first end of the terminal element and the connection area, and
wherein the pick and place unit comprises a gripping tool configured to grip the first end of the terminal element or a protrusion connected to the first end.

8. The system of claim 1, wherein the pattern recognition unit is configured to determine the actual position of the connection area and the actual position of the first end of the terminal element by a pattern recognition technique.

9. The system of claim 8, wherein the pattern recognition unit comprises at least one camera configured to capture at least one image of the base plate and the substrate arranged thereon.

10. A method, comprising:
determining an actual position of a connection area by a pattern recognition unit, wherein the connection area is arranged on or above a substrate of a semiconductor module, the substrate being arranged on a base plate;
determining an actual position of a first end of a terminal element by the pattern recognition unit, wherein the terminal element is attached to a housing arranged on the base plate such that the substrate is arranged within a volume defined by the housing;
determining a deviation between the actual position of the first end of the terminal element with respect to the actual position of the connection area;
moving a pick and place unit to the actual position of the first end determined by the pattern recognition unit;
picking up, by the pick and place unit, the first end of the terminal element; and
subsequently moving, by the pick and place unit, the first end to the actual position of the connection area determined by the pattern recognition unit.

11. The method of claim 10, further comprising:
forming a permanent connection between the first end of the terminal element and the connection area.

12. The method of claim 11, wherein forming the permanent connection comprises performing an ultrasonic welding process.
